(19) United States
(12) Patent Application Publication
(10) Pub. No.: US 2022/0078954 A1
(43) Pub. Date: Mar. 10, 2022

(54) Interconnectable Data Center Equipment Rack

(71) Applicant: Electromagnetic Associates LLC, North Augusta, SC (US)

(72) Inventor: Davidson Arthur Scott, North Augusta, SC (US)

(73) Assignee: Electromagnetic Associates LLC, North Augusta, SC (US)

(21) Appl. No.: 17/468,777

(22) Filed: Sep. 8, 2021

Related U.S. Application Data
(60) Provisional application No. 63/076,063, filed on Sep. 9, 2020.

(51) Int. Cl. H05K 9/00

(52) U.S. Cl. CPC H05K 9/0081; H05K 9/0062

(57) ABSTRACT

A data center equipment rack, including an electronic equipment enclosure defined by RF-shielded walls. Openings in the RF-shielded walls are provided for being aligned with complimentary-sized and shaped openings in one or more like data center equipment racks and adapted for permitting a shielded electromagnetic connection between two or more racks. At least one access door in the enclosure is provided for facilitating access to the electronic equipment in the rack. Panels are provided for covering the respective openings in the RF-shielded walls when the openings are not being used to permit an electromagnetic interconnection between two or more racks.

### CROSS-REFERENCE TO RELATED APPLICATIONS

This application claims priority from provisional patent application Ser. No. 63/076,063, filed on Sep. 9, 2020, the contents of which are incorporated by reference in this application.

### TECHNICAL FIELD AND BACKGROUND OF THE INVENTION

This invention relates to a scalable rack system for commercial Information Technology (IT), control, and communications equipment. The development of “data centers”, often referred to as “the cloud”, has evolved over the last couple of decades to support IT needs of companies, governments and individuals. The growth and expansion of the internet has allowed for the centralizing of “IT Processing” in such data centers.

Most enterprises in government, military, and industry rely on critical applications that are frequently hosted in central data processing hubs—whether commercial or proprietary data centers. Today, much, if not all internet commerce is dependent upon data centers. Data centers allow for enterprises to centralize and scale the specialized hardware and support staff required to operate their critical applications. Additionally, the data centers allow for the centralizing of support systems such as power, cooling, communication bandwidth, backup power, maintenance, software upgrades and many other functions that are costly for individual entities to maintain and operate. Commercial offerings such as “Amazon Web Services” host small-scale applications for individuals and industry as well as large-scale applications such as NetFlix with large data processing, storage and bandwidth requirements. Banking and financial entities have been centralizing IT operations in data centers for many years as computer processing has become more advanced and data storage costs have become far less expensive and more reliable. Government, including the military, intelligence community and other critical functions are hosting critical applications in data centers.

Data centers are by definition repositories of high-density computing equipment—processors, memory storage and the like. The capacity of these systems is continually being increased as cost is further reduced and additional applications are developed. These repositories are ideally designed and built to provide rapidly scalable architecture to accommodate frequent capacity additions. One aspect of this scalability is the development of rack systems which house the equipment. IT equipment has evolved into processing, communications, and storage elements that are housed in racks having a standard-sized profile. These are defined in EIA-310, the Electronic Industries Alliance standard for “Cabinets, Racks, Panels, and Associated Equipment”. This standard defines the dimensions and support requirements for standard profile electronic equipment. It defines a “Rack Unit” (RU, or sometimes simply “U”) to express the requirements for mounting electronic equipment that complies with the EIA-310 standard. Most IT equipment dimensions are expressed in “U” units which implies that it can be installed in a compliant “server rack”. This necessarily simplifies the scaling of IT capacity, which is critical to data center construction and operations.

A parallel concern that arises as the size of and reliance on these very large data centers increases is the danger of damage to the data centers from electromagnetic pulses, malicious or otherwise, which can destroy or significantly impair the operation of a data center. As a result of this concern, Electromagnetic Pulse (“EMP”) protection protocols have been and are being developed to protect critical data centers. In March of 2019, an Executive Order titled “Executive Order on Coordinating National Resilience to Electromagnetic Pulses” was issued.

Data centers are defined by the US Government as “Critical Infrastructure” and, as such, it must be protected from various threats, including natural disasters and protection of data centers against electromagnetic threats, such as EMP. This includes the entire threat family such as Nuclear Electromagnetic Pulse—from the detonation of a nuclear fission device at high-altitude, Intentional Electromagnetic Interference (“IEMI”) and natural phenomena such as Geomagnetic Disturbances (GMD, or “Solar Storms”).

Data centers are nodes of vulnerability for any advanced economy—government, finance, commerce, water utilities, power utilities, transportation, military, national security, among other basic functions of an advanced economy all depend on data centers and communication between data centers and end user applications. The loss, even a temporary loss, of functionality would have very large cascading effects upon such an economy.

Principles of protection against electromagnetic threats are known and defined. The US military has published the non-classified “MIL-STD-188-125” standard (hereafter “MIL-STD”) as well as other publications that provide for the specification and shielding of critical functions within an environment that is protected against electromagnetic threats. Additionally, the intelligence community has articulated “TEMPEST” requirements that prevent electronic emanations from being released from electronic equipment that could be exploited and decoded by an adversary. EMP/IEMI shielding prevents electromagnetic energy originating outside of a protected environment from entering and damaging systems inside the protected environment.

TEMPEST shielding prevents electromagnetic emanations that originate inside a protected environment from exiting and possibly being exploited by “Bad Actors” outside of the protected environment.

In typical IT/Data Center installations, racks are either “Open” (facilitating cooling, power, interconnection between racks) or “Enclosed” which allows for some control over access to equipment in individual racks, but also facilitates the connection/interconnection of racked equipment with other racks, power, and communications equipment required for IT systems and applications to operate. Each connection for power, communications, cooling, as well as any doors on racks to facilitate access is a potential vulnerability to EMP/HEMP/IEMI and TEMPEST.

There are “EMI” rack systems that are available for purchase commercially. These systems focus on maintaining a shielded environment within the rack system.

See:

https://hollandshielding.com/RF-shielded-racks,

https://www.equiptoelec.com/products/emi-rfi-shielded-cabinets/

http://www.ets-lindgren.com/datasheet/shielding/rf-shielded-enclosures/11003/1100310

These systems all function similarly within the enclosed volume of the cabinet.

“Electromagnetically secure” as used in this application means that electromagnetic field levels will not exceed MIL-STD-188-125-1/2, IEMI levels will not exceed EN55035, and Tempest ICD/ICS 705. These are not the only electromagnetic shielding performance standards, and the rack system is not tied to any specific standard. The rack system is expected to perform from 10 khz (or lower) to 10 ghz (or higher) frequency to a level where electromagnetically induced damage, disruption, upset, exploitation, as well as the physical protection of the contents of the racks is reliably accomplished. The rack systems include the use of cypher locks, card-reader access, magnetic latching or other physical protection means to present access by unauthorized personnel.

A need exists for an enhanced environment within which the evolving requirements of EMP/HEMP/IEMI and TEMPEST standards.

### SUMMARY OF THE INVENTION

It is therefore an object of the invention to provide data center equipment racks that are interconnectable with adjacent shielded racks without compromising shielding. It is another object of the invention to provide data center equipment racks that are interconnectable with racks above/below shielded racks without compromising shielding.

It is another object of the invention to provide data center equipment racks that are mobile, depending on size.

It is another object of the invention to provide protection for data center equipment from outside EMP/HEMP/IEMI threats.

It is another object of the invention to protect against electromagnetic emanations that originate inside from exiting a protected environment potentially being exploited outside of the protected environment.

According to one aspect of the invention, an equipment rack includes an electronic equipment enclosure defined by RF-shielded walls and a plurality of openings in the RF-shielded walls adapted for being aligned with complimentary openings in one or more like data center equipment racks and adapted for permitting a shielded electromagnetic connection between two or more racks. At least one access door is provided in the enclosure for facilitating access to the electronic equipment in the rack. Covers are provided for covering the respective openings in the RF-shielded walls when the openings are not being used to permit an electromagnetic interconnection between two or more racks.

According to another aspect of the invention, the enclosure includes at least one waveguide air intake/exhaust port.

It is another object of the invention to provide for a cooling system based on compressed gas that will pass through a “waveguide below cutoff” into the rack system and provide cooling through expansion of compressed gas, and the flow of compressed gas out of the rack system.

According to another aspect of the invention, an access door is provided in the enclosure for allowing access to an interior of the enclosure.

According to another aspect of the invention, an equipment rack is provided that includes an electronic equipment enclosure defined by RF-shielded top wall, bottom wall, first and second side walls and front and rear walls. A plurality of openings is provided in at least one top and at least one side wall of the RF-shielded wall and adapted for being aligned with complimentary openings in one or more like data center equipment racks and adapted for permitting a shielded electromagnetic connection between two or more racks. At least one access door is provided in the enclosure for facilitating access to the electronic equipment in the rack. Covers are provided for covering the respective openings in the RF-shielded walls when the openings are not being used to permit an electromagnetic interconnection between two or more racks.

According to another aspect of the invention, an opening is provided in each of the first and second side walls, the openings positioned respectively to allow mating alignment with each other for passage of connectors therethrough.

According to another aspect of the invention, an equipment rack assembly is provided that includes a plurality of RF-shielded equipment racks.

According to another aspect of the invention, at least one of the plurality of racks comprising the rack system is a different size than other of the plurality of racks.

Racks may be taller, wider, deeper, depending on application

According to another aspect of the invention, the racks include an access door on the front wall and the rear wall.

### BRIEF DESCRIPTION OF THE DRAWING FIGURES

The present invention is best understood when the following detailed description of the invention is read with reference to the accompanying drawings, in which:

FIG. 1 is a front isometric view of a data center equipment rack according to a preferred embodiment of the invention;

FIG. 2 is a rear isometric view of the data center equipment rack shown in FIG. 1;

FIG. 3 is a top plan view of the data center equipment rack shown in FIG. 1;

FIG. 4 is a front elevation of the data center equipment rack shown in FIG. 1;

FIG. 5 is a side elevation of the data center equipment rack shown in FIG. 1;

FIG. 6 is a cross-section of the data center equipment rack shown in FIG. 1, taken along line A-A of FIG. 4;

FIG. 7 is a cross-section of the data center equipment rack shown in FIG. 1, taken along line B-B of FIG. 4;

FIG. 8 is a front elevation showing a “racked and stacked” array of the data center equipment racks according to the invention;

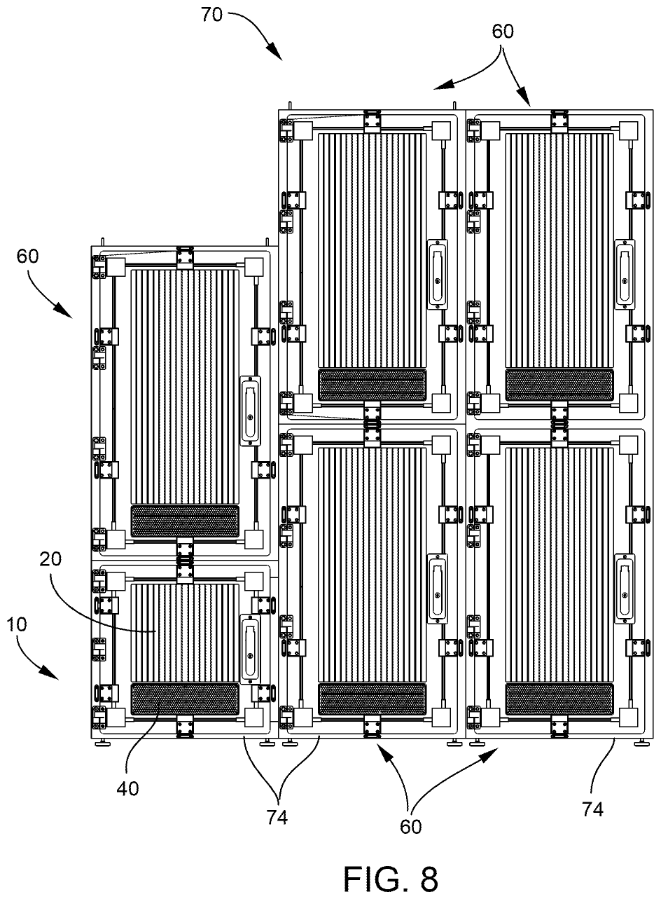

FIG. 9 is a top plan view of the array of data center equipment racks shown in FIG. 9;

FIG. 10 is a cross-section of the data center equipment racks shown in FIG. 9, taken along line C-C of FIG. 10; and

FIG. 11 illustrates a example installation of a line of rack systems at a data center.

### DETAILED DESCRIPTION OF THE PREFERRED EMBODIMENT AND BEST MODE

The development of the rack system as described in this application is directed towards the purpose of providing an electromagnetically secure environment within which any item, including IT equipment, communications equipment, control equipment, protective relay equipment, or any other electronic or non-electronic item may be placed. As described below, the described racks and rack system are interconnectable—above, below, beside, or through a protected umbilical structure.

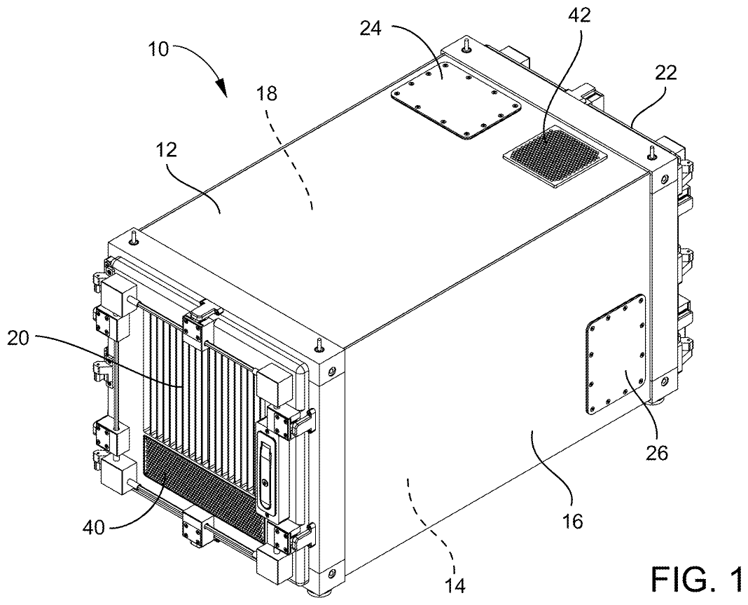

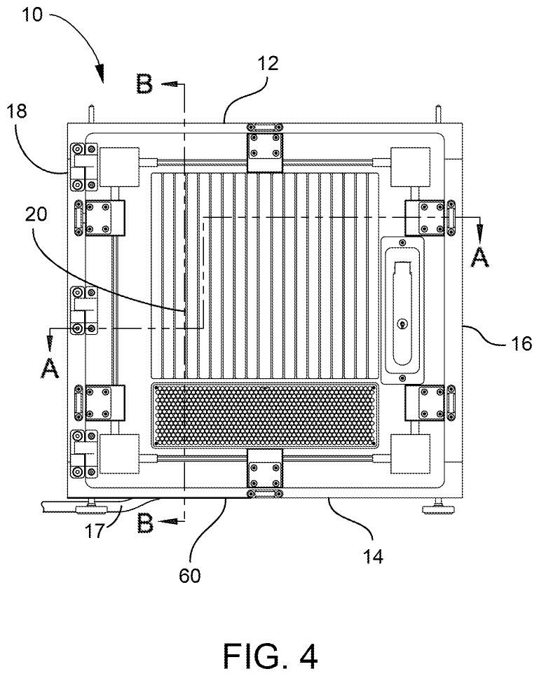

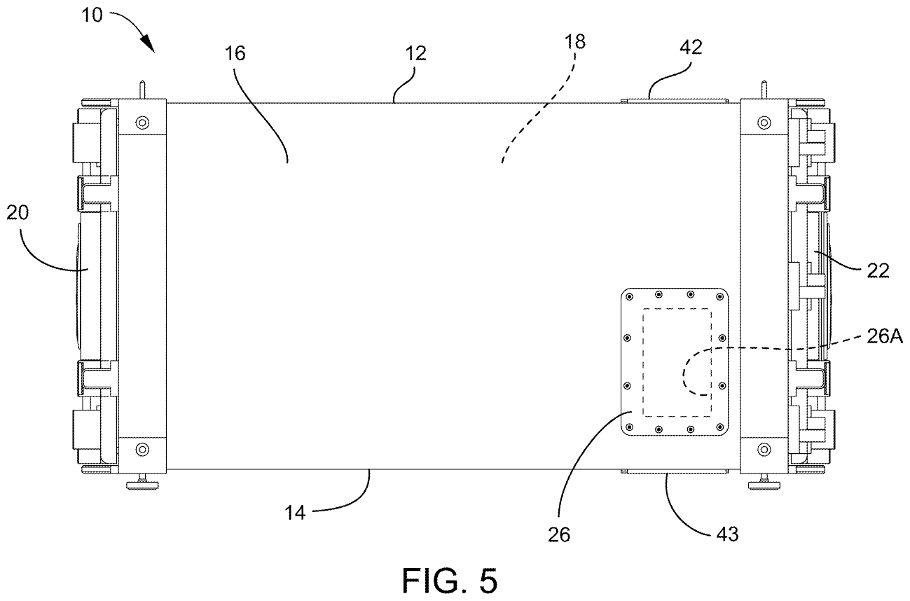

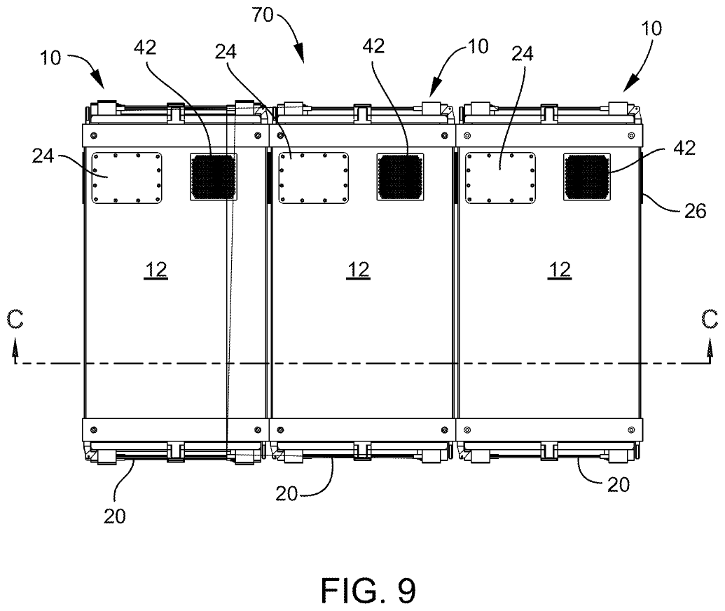

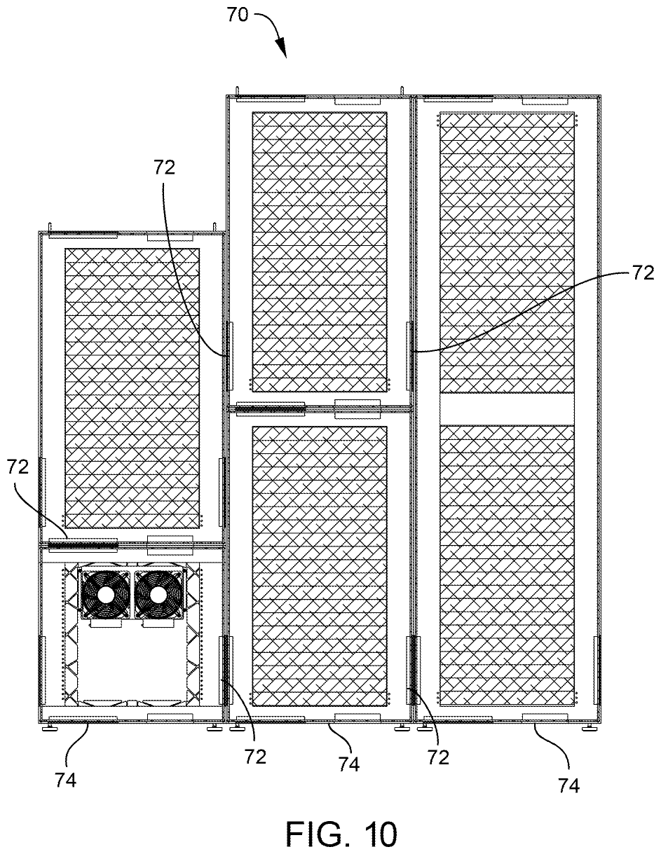

Various views of a rack 10 according to an embodiment of the invention are shown in FIGS. 1-7. The racks 10 can be interconnected to form a rack system 70 as shown in FIGS. 9-11, which is exemplary of a unlimited variety of interconnections dictated by the equipment being protected. The racks 10 may by larger or smaller depending on the requirements of what will be placed within.

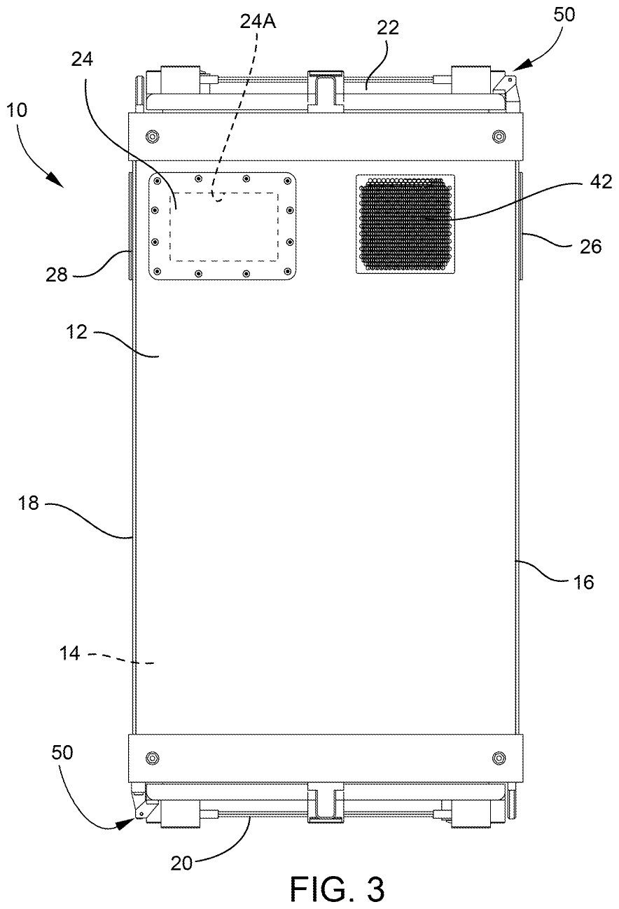

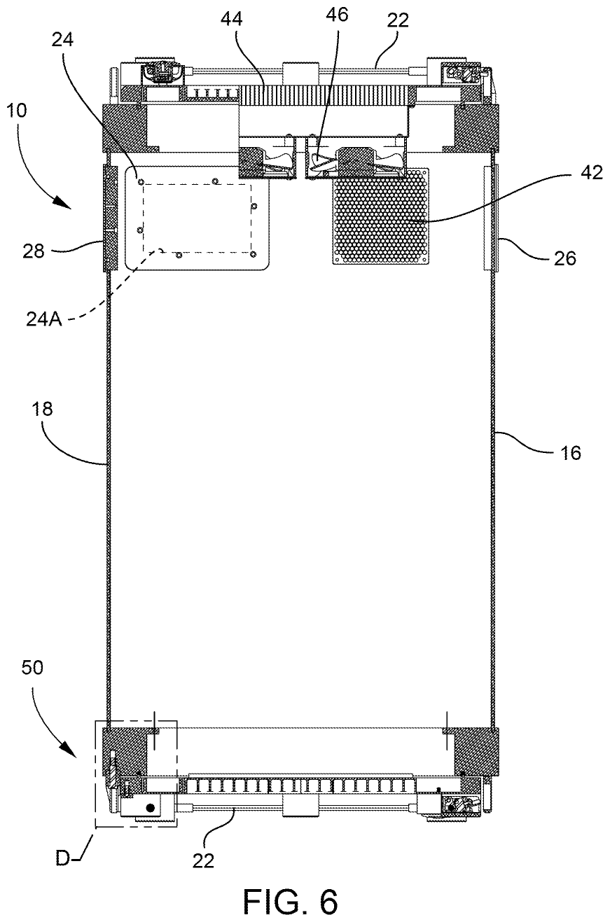

As shown collectively in FIGS. 1-7, the exemplary rack 10 is generally rectangular and includes a top wall 12, a bottom wall 14, side walls 16, 18, a front wall 20 and a back wall 22. The top wall 12 includes a removable cover 24, and the side walls 26 and 18. As best shown in FIGS. 3 and 6, the rack 10 includes removable covers 26 and 28, respectively. The removable covers 24, 26 and 28 match up to adjacent racks 10 and racks 10 above or below each rack 10 to define a rack system 70 as shown in FIGS. 9-11 without regard to the size of the racks 10. For illustrative purposes, the racks 10 are 10U racks.

With the covers 24, 26 and 28 removed, interconnection ports 24A, 26A and 28A are exposed for use. The size and location of the interconnection ports 24A, 26A and 28A can be of any size and location, as long as the ports 24A, 26A and 28A match up to ports in adjacent racks 10.

Penetrations may be integrated onto the interconnection ports 24A, 26A and 28A as required to connect and maintain the electromagnetic shielding environment inside the rack 10. Penetrations can be integrated into the cover 24, 26 and/or 28 of an otherwise unused interconnection port 24A, 26A and/or 28A. This is important to accommodate specific applications inside the rack 10. Sizes and types of penetrations can vary. The penetrations can include an umbilical attachment to cooling/power for “TIER IV+” data center protection.

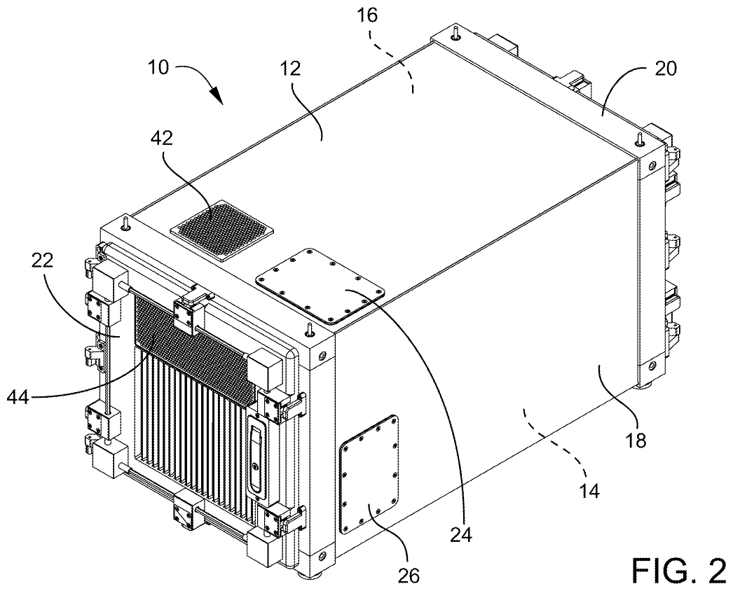

Referring collectively to FIGS. 1 and 2, air intake/exhaust port 40 in the front wall 20, air intake/exhaust port 42 in the top wall 12, air intake/exhaust port 43 in the bottom wall 14 and air intake/exhaust port 44 in the rear wall 22 are standard “waveguide below cutoff” intakes that pass air but not electromagnetic energy. This is a standard approach and not an innovation per se.

The air intake/exhausts 40, 42, 44 can be any size and in any location to accommodate specific needs of the user. As evident by its description, the air intake/exhausts 40, 42, 44 may either take cooling air into the rack 10 or exhaust warm air from the rack 10 depending on the direction of fan rotation. See by way of example, fan 46 of air intake/exhaust 44.

The rack 10 includes air waveguides, provisions for filters and other items. Because the racks 10 are interconnectable, each individual rack 10 does not need to have a filter, rather it can be connected to power in another rack 10 through the interconnection ports 24A, 26A and/or 28A.

Similarly, air flow, data cables, or any other required connection can be routed between racks 10 as needed. Also, a hose 17 may be provided to route compressed gas from a connector 15 to provide further cooling.

The racks 10 may be combined into multi-rack assemblies to form a rack system 70 shown in FIGS. 9, 10 and 11. As described above, the arrangement of individual racks 10 may be dictated by a wide variety of requirements and racks may be different sizes and dimensions as long as the covers are matched and aligned when mated together. In FIG. 9 a rack 10 as described above is shown assembled with five (5) racks 60 of a larger size to form the rack system 70. Dimensions support standard racks but this does not need to be the case. Racks can be taller, wider and deeper as required for the application. By way of example, a 10U rack 10 may have dimensions as follows: 24.75 in. (62.9 cm.) wide, 23.75 in. (60 cm.) high and 47.8 in. (121.5 cm.) deep. These dimensions support standard racks but this does not need to be the case. Racks can be taller wider and deeper as required for the application.

The rack system 70 can support a “power bus” architecture, whereby a single bus supplies power to a full row of racks 10, without each rack 10 having its own power supply. A common “rectifier cabinet” can provide power to all of the racks 10 in a row, and still maintain electromagnetic protections.

The racks 10 can have as many interconnection ports as required. Also, the interconnection ports facilitate the integration of special penetrations, as needed, by allowing for electromagnetically sealed penetrations for waveguides, air, liquid, fiber optic ports, or penetrations for any other purpose to be integrated into any available rack interconnection port.

The depictions shown in this application are one possible version of many possible rack designs. The racks can be taller, wider, or be sized to support any standard or non-standard rack unit mounting of equipment. The interconnections shown are just one way to assure interconnection between racks. These can include versions with more, fewer, larger or smaller interconnection ports using any shape interconnection port cover.

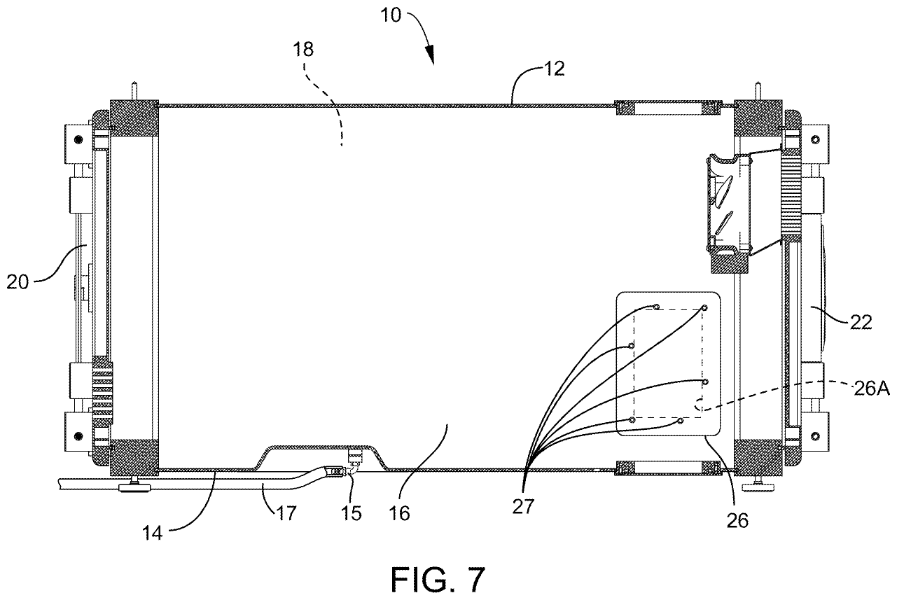

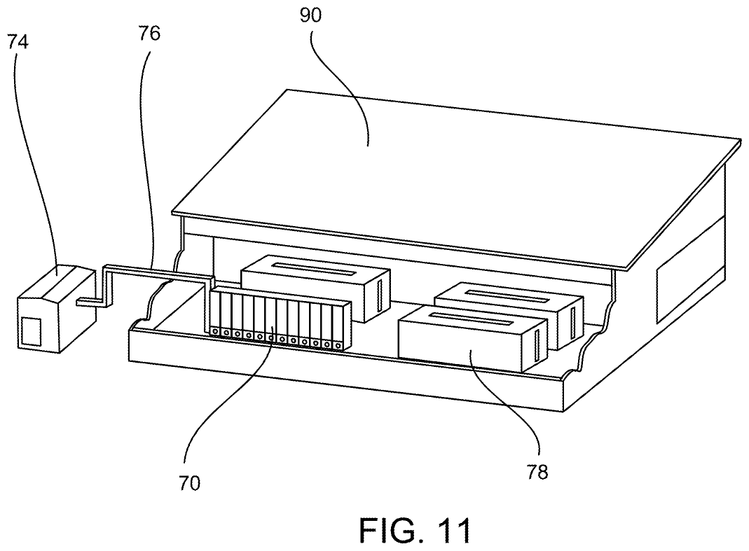

The interconnection ports exclude electromagnetic energy from entering the inside of the rack system, and the means of accomplishing this can be the use of any suitable form of gasketing, fingerstock, conductive pastes, or any other method that can support electromagnetic shielding and facilitate the removal of the interconnection port cover to support any configuration or change in configuration of racks over the life-cycle of the systems protected by the rack system. As best shown in FIG. 7, with the cover 26 removed, the interconnection port 26A is exposed, and has an array of holes 27 that also mate with matching aligned holes in the interconnection port of another rack 10. With the covers 26 removed, the aligned holes can receive screws, bolts or any other suitable connection with, as noted above, suitable gasketing, fingerstock, conductive pastes or other electromagnetic shielding. Actual connection of components may be by any suitable plug, cable, wire and jumper cable without regard to whether it is male/male, male/female, female/female or a unitary connector. Such examples are shown at reference numbers 72 of FIG. 11.

The cooling pedestal 74 is interconnected through an electromagnetically sealed umbilical to electromagnetically protected cooling modules (not shown) that can be located inside, outside or any other convenient location to provide dedicated cooling capacity to the rack system 70. The rack system 70 can also use cooling as provided by any typical data center environment.

The electromagnetically protected umbilical can also support the supply of power to the rack system and can be connected to an electromagnetically sealed generator dedicated to the support of the rack system and any associated mechanical systems.

The rack system 70 will support “built in test” through the use of electromagnetic emitters inside the protected environment of the rack system 70. These emitters can be used to assess the electromagnetic shielding environment and detect if there are any shielding leaks, or to perform periodic “verification testing” of the shielded environment. The built-in test will not impact any operational aspect of the equipment operating inside the rack system.

Another embodiment will include the use of an integrated filter as part of the rack assembly and will provide isolation from RF energy that may be present at harmful levels outside the new rack assembly. The rack system 70 can be mobile—the system may or may not have integrated wheels for mobility, and may or may not have handles allowing for the system to be transported.

The rack system will have RF ports built in to allow for the automatic testing of the rack system for Shielding Effectiveness per the MIL-STD. The rack system will have “Shielded Enclosure Leak Detection System” ports to allow for the injection of RF energy into loops or studs.

As shown in FIG. 11, an example installation of a line of rack systems 70 with EMP protected supplemental power/HVAC cooling facility 74 connected by an EMP protected power/cooling umbilical 76 is shown in a data center 90, together with standard, non-EMP protected racks 78 in the same data center 90.

A data center equipment rack and rack system according to the invention has been described with reference to specific embodiments and examples. Various details of the invention may be changed without departing from the scope of the invention. Furthermore, the foregoing description of the preferred embodiments of the invention and best mode for practicing the invention are provided for the purpose of illustration only and not for the purpose of limitation, the invention being defined by the claims.

What is claimed:

1. An equipment rack, comprising:
(a) an electronic equipment enclosure defined by RF-shielded walls;
(b) a plurality of openings in the RF-shielded walls adapted for being aligned with complimentary openings in one or more like data center equipment racks and adapted for permitting a shielded electromagnetic connection between two or more racks;
(c) at least one access door in the enclosure for facilitating access to the electronic equipment in the rack; and
(d) covers for covering the respective openings in the RF-shielded walls when the openings are not being used to permit an electromagnetic interconnection between two or more racks.

2. An equipment rack according to claim 1, and including at least one intake/exhaust port.

3. An equipment rack according to claim 1, and including a waveguide air intake/exhaust port.

4. An equipment rack according to claim 1, and including an access door in the enclosure for allowing access to an interior of the enclosure.

5. An equipment rack, comprising:
(a) an electronic equipment enclosure defined by RF-shielded top wall, bottom wall, first and second side walls and front and rear walls;
(b) a plurality of openings in at least one top and at least one side wall of the RF-shielded wall and adapted for being aligned with complimentary openings in one or more like data center equipment racks and adapted for permitting a shielded electromagnetic connection between two or more racks;
(c) at least one access door in the enclosure for facilitating access to the electronic equipment in the rack; and
(d) covers for covering the respective openings in the RF-shielded walls when the openings are not being used to permit an electromagnetic interconnection between two or more racks.

6. An equipment rack according to claim 5, and including an opening in each of the first and second side walls, the openings positioned respectively to allow mating alignment with each other for passage of connectors therethrough.

7. An equipment rack according to claim 5, and including mating attachment points in the enclosure and surrounding the openings to allow connection of adjacent racks at the openings.

8. An equipment rack according to claim 5, and including an air intake/exhaust port positioned in the top wall of the enclosure and an air intake/exhaust port positioned in the front wall of the enclosure.

9. An equipment rack system comprising a plurality of RF-shielded equipment racks, the racks comprising:
(a) an electronic equipment enclosure defined by RF-shielded walls;
(b) a plurality of openings in the RF-shielded walls adapted for being aligned with complimentary openings in one or more like data center equipment racks and adapted for permitting a shielded electromagnetic connection between two or more racks;
(c) at least one access door in the enclosure for facilitating access to the electronic equipment in the rack; and
(d) covers for covering the respective openings in the RF-shielded walls when the openings are not being used to permit an electromagnetic interconnection between two or more racks.

10. An equipment rack system according to claim 9, and including at least one intake/exhaust port.

11. An equipment rack system according to claim 9, and including a waveguide air intake/exhaust port.

12. An equipment rack system according to claim 9, and including an access door in the enclosure for allowing access to an interior of the enclosure, the door including a floating hinge for preventing pinching of gasket material sealing the door against the enclosure.

13. An equipment rack system comprising a plurality of RF-shielded equipment racks, the racks comprising:
(a) an electronic equipment enclosure defined by RF-shielded top wall, bottom wall, first and second side walls and front and rear walls;
(b) a plurality of openings in at least one top and at least one side wall of the RF-shielded wall and adapted for being aligned with complimentary openings in one or more like data center equipment racks and adapted for permitting a shielded electromagnetic connection between two or more racks;
(c) at least one access door in the enclosure for facilitating access to the electronic equipment in the rack; and
(d) covers for covering the respective openings in the RF-shielded walls when the openings are not being used to permit an electromagnetic interconnection between two or more racks.

14. An equipment rack system according to claim 13, and including an opening in each of the first and second side walls, the openings positioned respectively to allow mating alignment with each other for passage of connectors there through.

15. An equipment rack system according to claim 13, and including mating attachment points in the enclosure and surrounding the openings to allow connection of adjacent racks at the openings.

16. An equipment rack system according to claim 13, and including an air intake/exhaust port positioned in the top wall of the enclosure and an air intake/exhaust port positioned in the front wall of the enclosure.

17. An equipment rack system according to claim 13, wherein at least one of the plurality of racks comprising the rack system is a different size than other of the plurality of racks.

18. An equipment rack system according to claim 13, wherein the racks include an access door on the front wall and the rear wall.
